(19) United States
(12) Patent Application Publication
(10) Pub. No.: US 2003/0040276 A1
(43) Pub. Date: Feb. 27, 2003

(54) Method and apparatus to record and replay radio programs

(76) Inventor: Steve A. Corn, Tucson, AZ (US)

Correspondence Address: Dale F. Regelman, Law Office of Dale F. Regelman P.C., 4231 S. Fremont Avenue, Tucson, AZ, 85714, US

(21) Appl. No.: 10/226,397

(22) Filed: Aug. 23, 2002

Related U.S. Application Data
(60) Provisional application No. 60/314,493, filed on Aug. 23, 2001.

(51) Int. Cl. H04B 1/00; H04B 7/00; H04B 1/06; H05K 11/02

(52) U.S. Cl. 455/42; 455/66; 455/344

(57) ABSTRACT

A portable apparatus to record and replay one or more radio programs, where that portable apparatus includes a digital recorder, a tuner/player portion, a communication link interconnecting the recorder and the tuner/player, an antenna disposed around the periphery of the communication link, where the recorder, tuner/player, communication link, and antenna, are removeably disposed within a portable carrying case. The case is designed to position the recorder and tuner/player to minimize electromagnetic interference (EMI) emanating from the digital switching circuits in the recorder which could add noise in the sensitive tuner/player during recording.

### FIELD OF THE INVENTION

The invention relates to a method and a portable apparatus to record one or more radio programs, store those one or more radio programs, and replay those one or more radio programs.

### BACKGROUND OF THE INVENTION

The reception of radio broadcasts is generally time dependent. That is, a particular radio program can generally only be heard during its broadcast by a radio station. Needless to say, popular radio programs are generally broadcast at times conducive to maximizing the listening audience. These broadcast times, however, often overlap with the typical working hours of many listeners. Thus for many potential listeners, busy schedules and work obligations limit their radio listening times to daily commutes and/or exercise regimens which do not occur during the times when the most popular radio programs are broadcast. There are no existing methods to record radio programs that are automatic, use a portable apparatus, and which are easily used by the typical radio listener. Applicant's invention includes a portable programmable audio recorder and player. This invention provides a user with a portable apparatus, and a method using that portable apparatus, to enjoy radio programs by automatically recording one or more radio programs broadcast at different times, over the same, or differing, frequencies, using the same, or differing, broadcast modes. Those recorded programs can then be replayed at the listener's convenience. Additionally, Applicant's invention provides the user with a plurality of methods to replay the recorded audio programming, including use of a portable recorder unit, a tuner/playback unit, or a nearby FM radio.

Applicant's invention allows a user to listen to radio programs at a more convenient time than originally broadcasted. Using Applicant's apparatus and method, a listener need not be available when those programs are publicly broadcast. Applicant's apparatus and method allows a user to listen to the recorded audio using a lightweight, portable unit when exercising, or in the alternative using a nearby FM radio, such as the FM radio installed in a vehicle.

### SUMMARY OF THE INVENTION

The present invention provides a portable apparatus, and method using that portable apparatus, to record radio programs broadcast during a plurality of different time periods; using a plurality of different frequencies, stations, or channels; for a plurality of different broadcast programs. These broadcast programs include those found on AM radio, FM radio, TV (audio), NOAA Weather, and the like.

In one embodiment, the present invention comprises a portable apparatus to record and replay one or more radio programs, where that portable apparatus includes a digital recorder and a tuner/player removeably disposed in a portable carrying case. The case is specifically designed to position the recorder and tuner/player to minimize electromagnetic interference (EMI) emanating from the digital switching circuits in the recorder which could add noise in the sensitive tuner/player during recording. This embodiment includes a detachable, portable, pocket-sized digital recorder and a detachable, portable, pocket-sized tuner/player. These pocket-sized detachable units allow a listener to conveniently listen to either recorded or live broadcasts while walking or exercising.

Further embodiments of the present invention include an apparatus in the tuner/player comprising a digitally tuned FM transmitter which allows replay of recorded radio programs by rebroadcasting those recorded signals and receiving those rebroadcasts using an external FM radio in near vicinity to Applicant's apparatus. Alternative embodiments include a separate capacitively tuned FM transmitter and/or a cassette adapter with both options providing additional playback alternatives. Another alternative embodiment includes a tuner/player capable of playing back recorded audio utilizing an audio amplifier and internal speaker. Further embodiments include a novel Input Signal Detection (ISD) mode in the digital recorder that provides for maximum battery efficiency by turning off all of the digital signal processing when there is no audio to record.

One embodiment of Applicant's apparatus includes an AM/FM radio, an FM transmitter and/or cassette adapter, and a digital recorder with a programmable timer mode. These three components are interconnected using Applicant's communication link, and are housed in a custom case that both protects the apparatus and positions the radio relative to the digital recorder to minimize EMI emanating from the digital recorder.

The invention will be better understood from a reading of the following detailed description taken in conjunction with the drawings. Applicant's invention, however, is not limited by these exemplary embodiments, and includes any and all modifications that may be apparent to one skilled in the art.

### BRIEF DESCRIPTION OF THE DRAWINGS

FIG. 1 is a block diagram of Applicant's programmable apparatus that includes a digital recorder, a tuner/playback unit, a communication link, as well as alternate embodiments including an FM transmitter and/or a cassette adapter;

FIG. 2 is a block diagram of one embodiment of Applicant's tuner/playback unit which includes a programmable PLL radio, a playback mode switch circuit, a novel PLL tuned FM transmitter, and an amplifier/speaker circuit;

FIG. 3 is a front view of one embodiment of Applicant's tuner/playback unit illustrating one configuration of programming buttons, playback mode buttons, clock, and speaker;

FIG. 4 is a block diagram of one embodiment of Applicant's digital recorder that includes an Input Signal Detection circuit;

FIG. 5 is a flowchart that summarizes Applicant's method to record audio broadcasts;

FIG. 6 is a flowchart that summarizes Applicant's method to replay previously recorded audio broadcasts;

FIG. 7 is a perspective view showing one embodiment of Applicant's portable carrying case where that case is in an open configuration;

FIG. 8 is a perspective view showing the carrying case of FIG. 7 in a closed configuration.

### DETAILED DESCRIPTION OF PREFERRED EMBODIMENTS

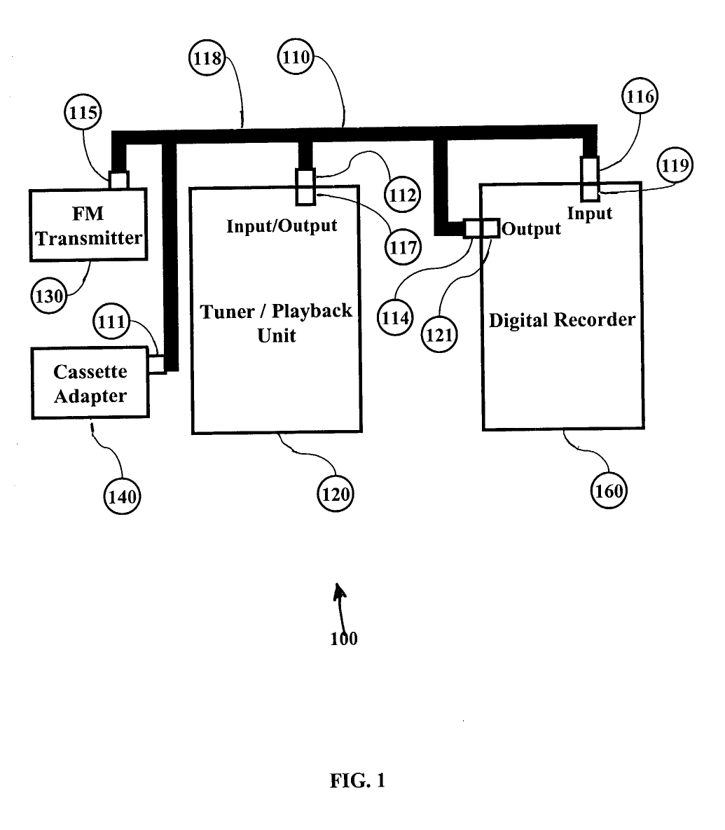

Referring to FIG. 1, apparatus 100 includes tuner/playback unit 120, digital recorder 160, and communication link 110. Communication link 110 includes first connector 111, second connector 112, third connector 113, fourth connector 114, and fifth connector 115. Second connector 112 is releaseably connected to tuner/playback unit 120. In one embodiment, second connector 112 connects to tuner/playback unit 120 using audio input/output jack 117.

Communication link 110 further includes metallic jacket 118. Tuner/playback unit 120 utilizes jacket 118 as an antenna for reception of higher frequencies such as those used in the FM, TV, and NOAA Weather bands, and for transmission of an FM signal in certain playback embodiments. Fourth connector 114 is releaseably connected to digital recorder 160. In one embodiment, fourth connector 114 releaseably connects to audio output jack. 121. Third connector 116 is releaseably connected to digital recorder 160. In one embodiment, third connector 116 releaseably connects to microphone input jack 119. In one embodiment, a matching network is integrated into third connector 116 to match the audio output of the tuner/playback unit 120 to the microphone input of digital recorder 160.

Alternative embodiments of apparatus 100 include a separate capacitively tuned FM transmitter 130. Yet other embodiments include cassette adapter 140 with the appropriate additions to interconnect communication link 110 to provide additional options for listening to the recorded radio programs.

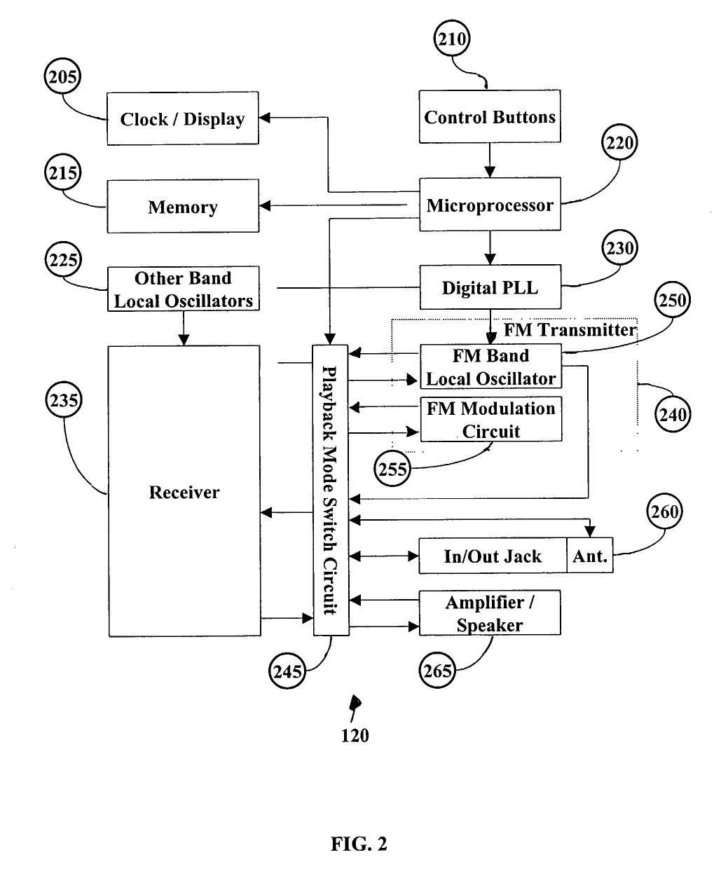

Referring to FIG. 2, tuner/playback unit 120 includes clock/display 205, control buttons 210, memory 215, and microprocessor 220 and its associated embedded software all of which together allow control and feedback of the various clock, radio, and programmable features of the tuner/playback unit. These features include setting the time and date for the clock, selecting operating modes for the tuner/playback unit, storing frequencies in preset memory locations for rapid tuning, and storing frequency, start time, and stop time events to automatically turn the tuner on and off at specific times and frequencies for recording radio programs.

The tuner component in tuner/playback unit 120 is a digitally tuned phase-locked-loop (PLL) controlled multi-band radio. In one embodiment, the tuner component provides for reception of AM, FM, TV (audio), and NOAA Weather broadcasts. In other embodiments the tuner component provides for reception of short wave (AM/USB/LSB) and/or marine, air traffic, police, and public safety frequencies. The tuner component comprises Digital PLL 230, FM Band Local Oscillator 250, Other Band Local Oscillators 225, First Receiver 235, and Audio In/Out Jack 260. In certain embodiments, tuner component 120 further includes a Second Receiver (not shown in FIG. 2), such that the First Receiver can receive a first radio signal and the Second Receiver can simultaneously receive a second radio signal. The first radio signal and the second radio signal have differing frequencies, where those differing frequencies may be in different broadcast bands. For example, the first radio signal may comprise an AM radio program and the second radio signal may comprise an FM radio program.

In certain embodiments, a ferrite bar antenna internal to the tuner component is used for the AM broadcast band antenna. Jacket 118 of communication link 110 (shown in FIG. 1) is used as an antenna for reception of higher frequencies such as for FM, TV, and NOAA Weather broadcasts.

Playback elements in the tuner/playback unit 120 include the Playback Mode Switch Circuit 245, Amplifier/Speaker 265, and FM Transmitter 240. The novel FM Transmitter 240 is made up of the existing digitally tuned FM Band Local Oscillator 250 and FM Modulation Circuit 255. Design of FM Modulation Circuit 255 is dependent upon the implementation of the FM Band Local Oscillator 250. The design can range from a simple monophonic FM modulator circuit to a more complex stereo FM modulator circuit. In certain embodiments, Applicant's apparatus includes the appropriate pre-emphasis circuitry. Pre emphasis techniques are used to improve signal-to-noise ratios. In certain embodiments, Applicant's pre emphasis circuitry follows a 6 dB per octave rate. This means that as the frequency doubles, the amplitude increases 6 dB.

When the user selects the Playback mode with Control Buttons 210, Microprocessor 220 and its associated embedded software provide the appropriate control signals to Playback Mode Switch Circuit 245 and Digital PLL 230. The control signals cause the Playback Mode Switch Circuit 245 to route the audio signal at Audio In/Out Jack 260 to FM Modulation Circuit 255 which is then used to modulate FM Band Local Oscillator 250. The control signals also cause the Playback Mode Switch Circuit 245 to route the transmitted output of FM Band Local Oscillator 250 to the ground terminal of Audio In/Out Jack 260 in order to utilize the shield along the whole length of Communication link 110 (shown in FIG. 1) as the FM transmit antenna.

In addition, control signals provided by Microprocessor 220, and the associated software stored in memory 221 (not shown in FIG. 2), to Digital PLL 230 while in Playback mode enable operation of FM Band Local Oscillator 250. In one embodiment, the frequency of FM Band Local Oscillator 250 is offset downwardly by about 10.6 MHz when compared to FM receiver operation to enable FM transmitter tuning from about 88 MHz to about 108 MHz. This downward offset is required because the FM LO in typical receivers is 10.6 MHz higher than the tuned frequency and thus normally tunes from 98.6 MHz to 118.6 MHz. In addition, Microprocessor 220, and its associated software, provide a frequency indication on Clock/Display 205 that reflects the actual transmitted frequency. Thus, FM Transmitter 240 will broadcast the audio at Audio In/Out Jack 260 on a precisely controlled, digitally tuned frequency as displayed on Clock/Display 205 anywhere from about 88 MHz to about 108 MHz. FM Modulation Circuit 255, FM Band Local Oscillator 250, communication link 110 (FIG. 1) are together adjusted to fully comply with the applicable regulations promulgated by the United States Federal Communication Commission and set forth in 47 C.F.R. Part 15.

In certain other embodiments the Playback mode will also provide audio amplification and playback of the audio signal at the Audio In/Out Jack 260 through the tuner/playback unit's speaker. This is accomplished by providing control signals from Microprocessor 220 to Playback Mode Switch Circuit 245 to route the audio signal at Audio In/Out Jack 260 to Amplifier/Speaker 265. In this manner the user can use Tuner/Playback Unit 120 for higher quality as well as higher volume listening than can be derived from the small speakers on pocket digital recorders. When Playback mode is not selected the audio signal from Receiver 235 output is routed to Amplifier/Speaker 265 and out to Audio In/Out Jack 260.

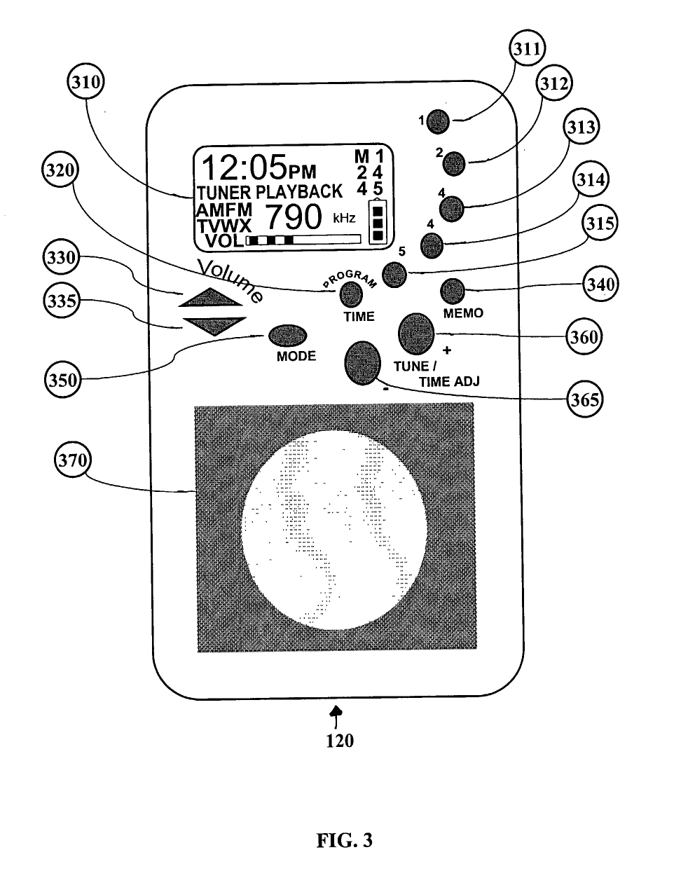

Referring now to FIG. 3, one embodiment of tuner/playback unit 120 includes display 310 that shows time, mode of operation, frequency band, frequency, volume level, battery level, and memory location selected. The user selects the mode of operation by pressing MODE button 350 which sequentially selects TUNER modes AM, FM, TV, WX, then PLAYBACK mode cycling back to TUNER mode AM.

When PLAYBACK mode is selected the FM transmitter is enabled for broadcasting the recorded audio from the digital recorder to a nearby FM radio on the precise frequency shown in display 310. The user adjusts the frequency by pressing TUNE/TIME ADJ + and − buttons 360 and 365. The user stores preset frequencies by pressing MEMO button 340 and one of memory buttons 311, 312, 313, 314, or 315. The user adjusts the time by pressing PROGRAM-TIME button 320 while the unit is off and then pressing TUNE/TIME ADJ + and − buttons 360 and 365. The user stores a programmable radio event by pressing PROGRAM-TIME button 320 while the unit is on, one of memory buttons 311, 312, 313, 314, and 315, and TUNE/TIME ADJ + and − buttons 360 and 365 in a given sequence that allows the required data to be stored in memory. Speaker 370 is used for listening to live broadcasts while in tuner mode or recorded broadcasts from digital recorder 160 while in playback mode. The volume level is adjusted by pressing Volume buttons 330 and 335.

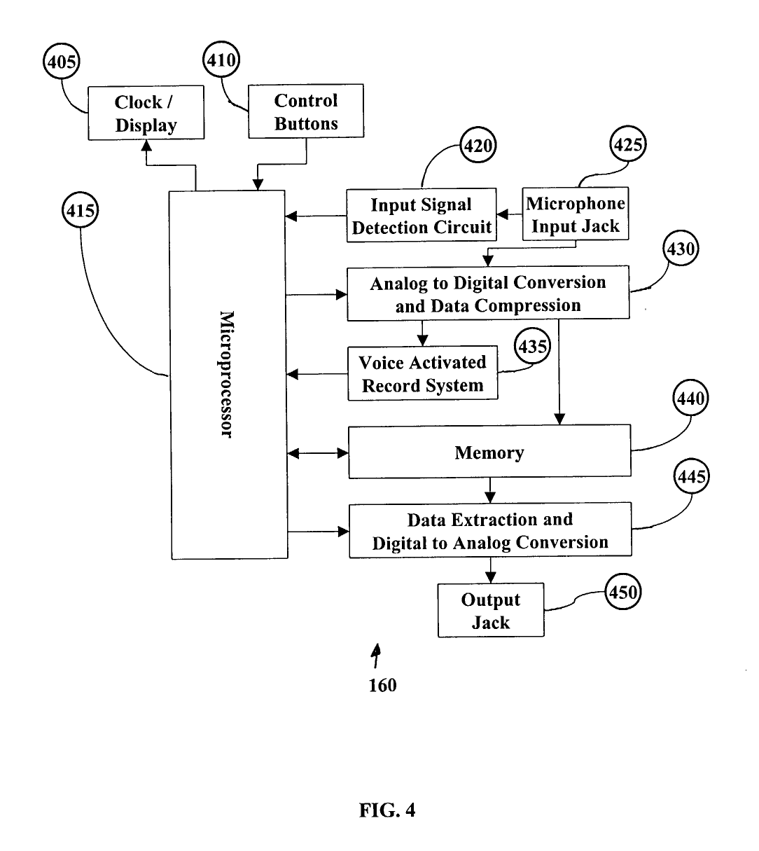

Referring to FIG. 4, Digital Recorder 160 includes Clock/Display 405, Control Buttons 410, Memory 440, and Microprocessor 415 using software stored in memory 440 which is in communication with Microprocessor 415, all of which together allow control and feedback of the various record and playback features.

Digital Recorder 160 records audio signals at Microphone Input Jack 425 by converting the analog audio signal to digital words and compressing the digital words to minimize memory requirements with Analog to Digital Conversion and Data Compression 430. This compressed digital word stream is then stored in Memory 440. Digital Recorder 160 plays the recorded audio signal by sending the compressed digital word stream stored in Memory 440 to Data Extraction and Digital to Analog Conversion 445 to create an analog replica of the digitally stored audio which is then sent to Output Jack 450.

In one embodiment, Digital Recorder 160 has four modes for recording the signal at Microphone Input Jack 425. The first mode, i.e. the manual mode, is enabled via the control buttons.

The voice activated mode is the second mode and uses Voice Activated Record System 435 to monitor the digitized word stream representing the signal provided by the Analog to Digital Conversion and Data Compression 430. In this mode if the signal is above a preset level, Voice Activated Record System 435 enables the storage of data in Memory 440. If the input signal drops below a preset level, Voice Activated Record System 435 halts the storage of the data stream in Memory 440 and continues analyzing digitized data stream representing the input data to determine when to begin storing the data stream in memory again.

The third recording mode is timer recording and is enabled when a user programmed start time occurs, and is disabled when a user programmed stop time occurs. This mode helps to maximize battery life by keeping the digital signal processing circuits off until the programmed time occurs. In certain embodiments multiple start and stop times can be programmed.

The fourth recording mode is an input signal detection (ISD) mode. In this mode all digital signal processing is turned off and only Clock/Display 405 and Input Signal Detection System 420 remain operational resulting in a very low battery current drain. When an input signal at Microphone Input Jack 425 is detected by Input Signal Detection Circuit 420, then Microprocessor 415, Analog to Digital Conversion and Data Compression 430, and Memory 440 are activated in the record mode. When Input Signal Detection Circuit 420 detects the absence of an input signal at Microphone Input Jack 425, then Microprocessor 415, Analog to Digital Conversion and Data Compression 430, and Memory 440 are deactivated.

The fourth mode differs from previously described voice activated mode in that the digital recorder's analog to digital and digital signal processing circuits are completely shut off reducing battery current drain by 95% or more. The ISD circuit includes an audio detector with an appropriately long integration time to deliver a logic signal to the power control circuit disposed in the digital recorder portion. The long integration time is required to allow the implementation of a very low current audio detection circuit as well as prevent the recorder from being halted during typical dead times of several seconds or more found in some broadcast radio programs. The ISD mode, due to its low current analog circuit implementation, will be too slow to respond for use in voice recording but is ideally suited for use in the radio program recorder. This input signal detection recording mode provides the radio program recorder user with the most efficient use of battery power without using the more complicated timer recording mode.

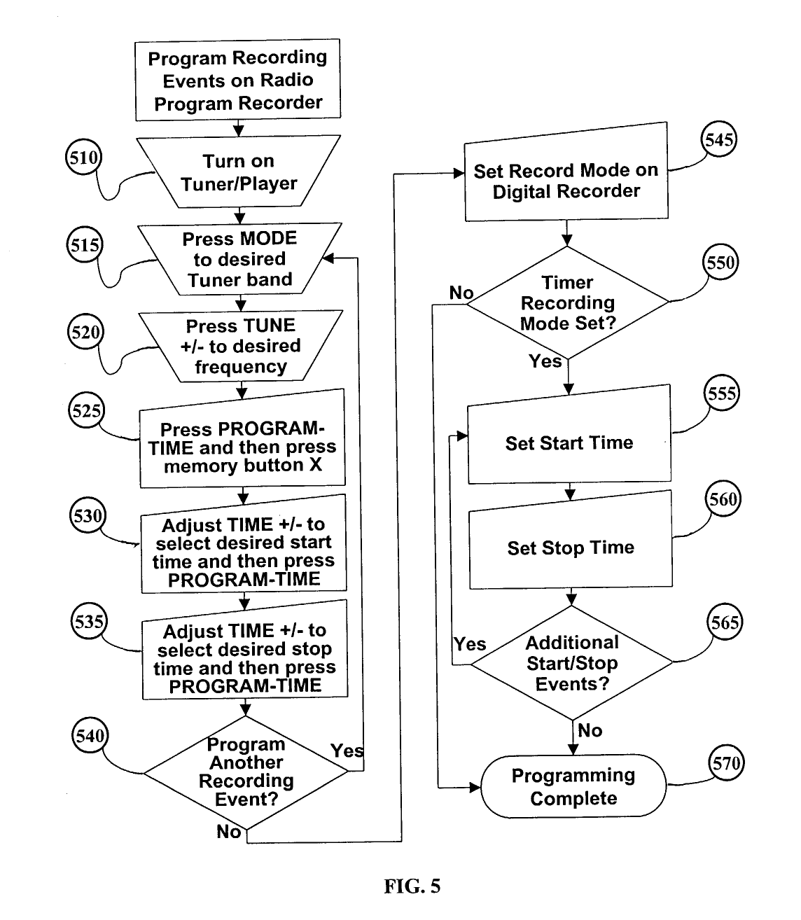

FIG. 5 summarizes the steps of Applicants' method to program the recording of radio broadcasts with the radio program recorder. In step 510 the user turns the tuner/player power on. In step 515 the user selects the desired broadcast band. In one embodiment, each press of the mode button would sequence the tuner/player through modes Tuner-AM, Tuner-FM, Tuner-TV, Tuner-Weather, Playback-FM, and back to Tuner-AM. In step 520 the user selects the desired frequency within the selected broadcast band using the TUNE +/− buttons. Alternatively the user can select a previously preset frequency by pressing one of the five memory buttons to instantly tune to a favorite frequency.

The user then begins the process of storing radio program events in step 525 by pressing the PROGRAM-TIME button whereupon the frequency display will flash indicating the selected frequency is ready for storage in memory. The user then selects a memory location and stores the frequency by pressing one of the five memory buttons. At this point the time display would then flash indicating the need to select a start time for storage in memory. In step 530 the user would use the TIME +/− buttons to adjust the display to the desired start time which is then stored in memory by pressing the PROGRAM-TIME button. At this point the desired frequency and start time are in the memory location selected in step 525 and the time display then flashes with the start time indicating the need to select a stop time for storage in memory. In step 535 the user would use the TIME +/− buttons to adjust the display to the desired stop time which is then stored in memory by pressing the PROGRAM-TIME button. At this point the desired frequency, start time, and stop time are all in the memory location selected in step 525 and the time display then reverts back to present time indicating completion of programming the event.

In the event the user in step 540 desires to program additional start times/stop times/frequencies, then steps 515 through 535 are repeated for each additional recording event. After programming the tuner/player the user then sets the record mode on the digital recorder in step 545. As indicated previously the record modes available for certain embodiments include manual recording, voice activated system recording, ISP recording, and timer recording.

As indicated in step 550, if the user does not select timer record mode then the programming for the radio program recorder is complete as shown in step 570. If the user selects Timer Recording mode then the start time and stop time need to be set as shown in steps 555 and 560. For certain embodiments multiple timer recording events can be set and for each event steps 555 and 560 would be repeated as shown in step 565. At this point programming of the radio program recorder is complete as shown in step 570 and recording will commence when the tuner/player turns on and the recorder is activated as determined by the recording mode set in step 545.

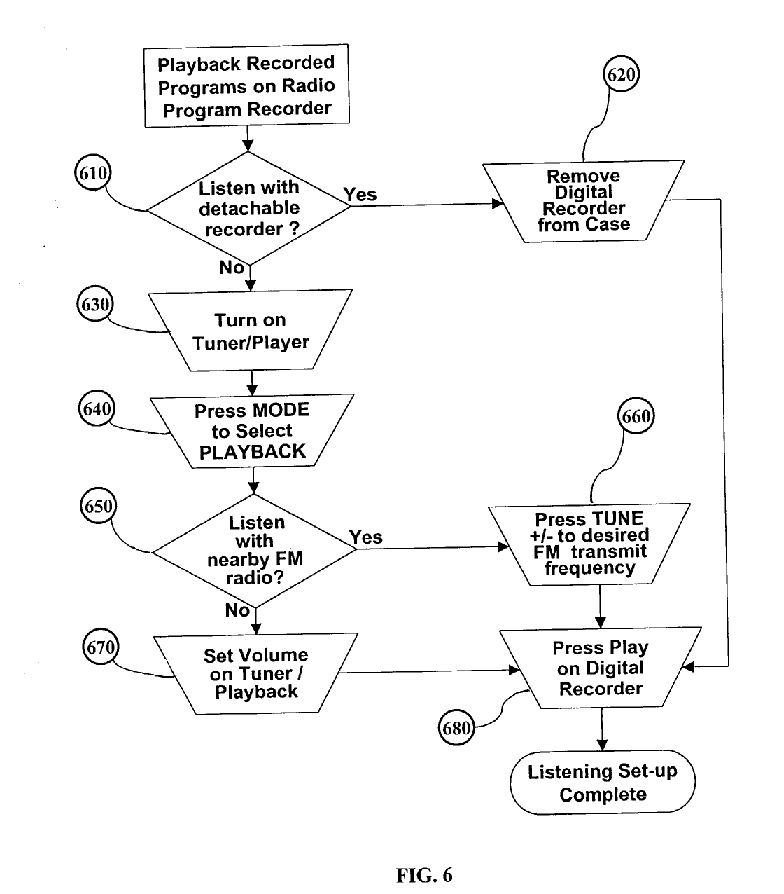

FIG. 6 summarizes the steps of Applicants' method to replay one or more previously recorded radio programs using Applicant's apparatus. If the user wants to listen to the recorded programs with maximum portability for use in a pocket, for example while walking or jogging, the digital recorder is easily removed from the radio program recorder as shown in steps 610 and 620. In step 630, the user turns on the tuner/player, and selects the Playback mode in step 640.

To listen to the recorded programs through a nearby FM radio, the TUNE +/− buttons are used to select the desired transmit frequency as shown in steps 650 and 660. The nearby FM radio will need to be tuned to the exact frequency indicated in the tuner/player display. If the user wants to listen to the recorded programs through the tuner/player's internal speaker, the Volume buttons would be used to select a comfortable listening level as indicated in step 670.

For all methods indicated above playback commences when the Play button on the digital recorder is pressed as indicated in step 680. Recorded playback can also be programmed to occur at a specific start and stop time, and even transmitted on a specific FM frequency if the playback mode is selected while programming the tuner/player for on/off events as indicated in FIG. 5. For this programmed playback option to be realizable the digital recorder must have a timer play mode. In this manner the radio program recorder can be used as an alarm clock that wakes the user up to his favorite radio program.

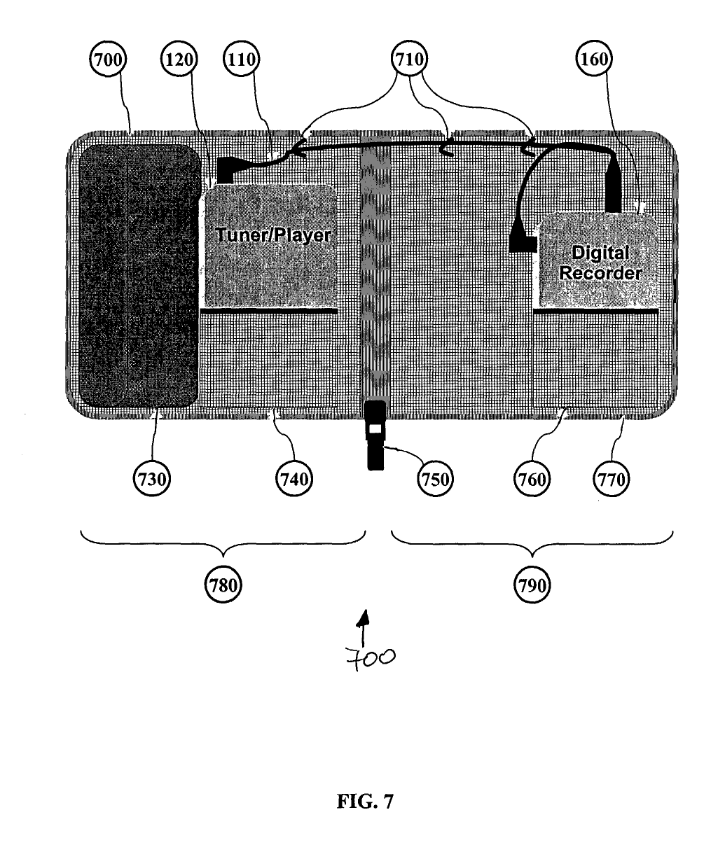

FIG. 7 shows one embodiment of Applicant's portable carrying case 700. Tuner/playback unit 120 (FIG. 1), digital recorder 160 (FIG. 1), and communication link 110 (FIG. 1) are shown disposed in carrying case 700. Tuner/player 120 is held in place by elastic mesh pocket 740 while digital recorder 160 is held securely in place by elastic mesh pocket 760. Communication link 110 is held securely in place by a series of elastic straps 710. In certain embodiments, carrying case 700 includes an accessory pouch 730. In an alternate embodiment if tuner/player 120 does not include an FM transmitter, accessory pouch 730 is replaced with an additional elastic mesh pocket to securely hold FM Transmitter 130 (FIG. 1).

Some advantages to use of carrying case 700 include its compactness and its ability to entirely contain and protect Applicant's apparatus without any external parts, cables, or wires. Placement of tuner/playback unit 120 relative to digital recorder 160 is significant. Applicant's carrying case fixtures the components of Applicant's apparatus such that electromagnetic interference (EMI) radiated from the digital recorder 160 does not interfere with, or degrade, the radio signal during reception by tuner/playback unit 120. Alternative embodiments of case 700 include EMI shielding surrounding or encasing the digital recorder 160 to minimize interference to the tuner/player unit 120. Such embodiments include metal enclosures and/or flexible metalized pockets with EMI closures.

Carrying case 700 further comprises first portion 780 and second portion 790. Case 700 may be folded such that portion 780 overlaps portion 790. In certain embodiments, a closure mechanism is disposed on periphery 770 to allow portion 780 to be releaseably attached to portion 790. In certain embodiments, this closure mechanism comprises a hook and loop combination. Such a hook and loop closure mechanism is sold commercially under the trade name VELCRO. In other embodiments, this closure mechanism comprises zipper mechanism 750. In alternative embodiments, buttons, magnets, and the like are used.

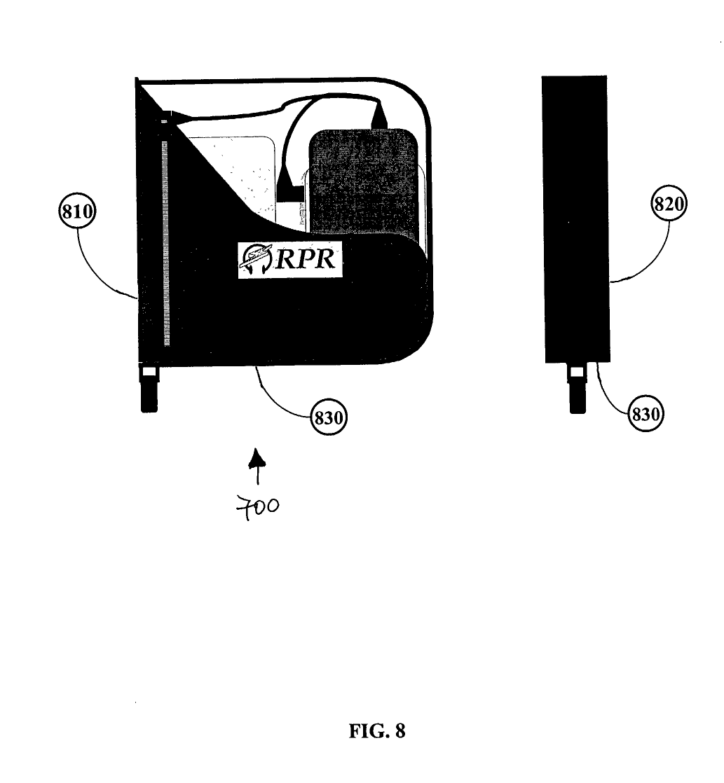

FIG. 8 is a diagram further illustrating the portability of Applicant's carrying case 700. As seen from the front view 810 of folded configuration 830 and the side view 820 of folded configuration 830, all components of Applicant's apparatus are contained within the confines of case 700. Additionally, the required spatial relationship between the tuner/playback unit 120 and digital recorder 160 discussed above is maintained when the case 700 is placed in configuration 830.

In certain embodiments, the individual steps recited in FIGS. 4 and/or 5 may be combined, eliminated, or reordered.

Applicants' invention includes an article of manufacture comprising a computer useable medium having computer readable program code disposed therein for forming one or more premigration aggregates, where each of those one or more premigration aggregates comprises one or more individual virtual volumes. Applicants' invention further includes computer program products embodied as program code stored in one or more memory devices, such as a magnetic disk, a magnetic tape, to form one or more premigration aggregates, where each of those one or more premigration aggregates comprises one or more individual virtual volumes.

While the preferred embodiments of the present invention have been illustrated in detail, it should be apparent that modifications and adaptations to those embodiments may occur to one skilled in the art without departing from the scope of the present invention as set forth in the following claims.

I claim:

1. A portable apparatus to record and playback radio programs, comprising:
a tuner portion;
a recorder portion;
a flexible enclosure comprising two internal pockets and electromagnetic shielding, wherein said tuner portion is removeably disposed in a first internal pocket, and wherein said recorder portion is removeably disposed in a second internal pocket, and wherein said electromagnetic shielding is disposed between said tuner portion and said recorder portion; and
a communication link interconnecting said tuner portion and said recorder portion, wherein said communication link includes a first connector, a second connector, a third connector, a fourth connector, and a fifth connector, wherein said second connector is releaseably attached to said tuner portion, and wherein said third connector and said fourth connector are releaseably attached to said recorder portion.

2. The apparatus of claim 1, further comprising an antenna, wherein said antenna comprises a metallic jacket disposed around said communication link.

3. The apparatus of claim 2, wherein said tuner portion further comprises:
an FM transmitter, wherein said fifth connector is releaseably attached to said FM transmitter;
a first receiver disposed in said tuner portion; and
a cassette adapter, wherein said first connector is releaseably attached to said cassette adapter.

4. The apparatus of claim 3, wherein said FM transmitter comprises:
an FM band local oscillator;
a pre-emphasis circuit; and
an FM modulation circuit.

5. The apparatus of claim 4, wherein said FM modulation circuit comprises a monophonic FM modulator circuit.

6. The apparatus of claim 4, wherein said FM modulation circuit comprises a stereo FM modulator circuit.

7. The apparatus of claim 3, further comprising a second receiver, wherein said first receiver is capable of receiving at a first time second radio signals having first frequencies, and wherein said second receiver is capable of receiving at said first time second radio signals having second frequencies.

8. The apparatus of claim 7, wherein said first frequencies differ from said second frequencies.

9. The apparatus of claim 8, wherein said recorder portion is capable of storing said first radio signals and said second radio signals.

10. The apparatus of claim 1, wherein said recorder comprises:
a battery power source;
an analog to digital processing circuit which receives power from said power source;
a digital signal processing circuit which receives power from said power source;
an input signal detection circuit, wherein said input signal detection circuit monitors said fourth connector for incoming signals, wherein said input signal detection circuit which shuts off power to said analog to digital processing circuit and to said digital signal processing circuit if no incoming signals are detected.

11. The apparatus of claim 10, wherein said recorded further comprises:
a voice activated record circuit, wherein said voice activated record circuit monitors the digitized word stream provided by said analog to digital processing circuit, and wherein said voice activated record circuit enables data storage if said digitized word stream exceeds a preset level.

12. A method to record and replay one or more radio programs, consisting of the steps of:
providing a portable apparatus comprising a first receiver, a digital recorder, a communication link interconnecting said receiver and said recorder, and an antenna comprising a metallic jacket disposed around said communication link;
providing a second receiver external to said portable apparatus;
receiving at a first time a first radio signal comprising first information and a first frequency;
recording said first information on said recorder;
transmitting at a second time a second radio signal, wherein said second radio signal comprises said first information and a second frequency;
receiving said second radio signal using said second receiver;
audibly emitting said first information.

13. The method of claim 1 1, wherein said second frequency is between about 85 megahertz and about 120 megahertz.

14. The method of claim 11, wherein said first frequency is between about 85 megahertz and about 120 megahertz.

15. The method of claim 11, wherein said first frequency is between about 600 kilohertz and about 1600 kilohertz.

16. The method of claim 11, further comprising the steps of:
providing an audio signal from said recorder;
routing said audio signal to said FM modulation circuit;
modulating using FM modulation circuit at said second frequency to form said second signal;
providing said second signal to said metallic jacket; and
radiating said second signal.

17. The method of claim 16, further comprising the step of:
offsetting downwardly said second frequency by about 10.6 megahertz.

18. The method of claim 17, wherein said portable apparatus further comprises a second receiver, further comprising the steps of:
receiving at said first time a third radio signal, wherein said third radio signal comprises second information and a third frequency;
recording said second information;
transmitting at a third time a fourth radio signal, wherein said fourth radio signal comprises said second information and said second frequency;
receiving said fourth radio signal using said second receiver; and
audibly emitting said second information.

19. The method of claim 11, further comprising the step of:
selecting a recording mode, wherein said selected recording mode comprises a manual mode, a voice activated mode, a timer recording mode, and an input signal detection mode.

20. The method of claim 19, wherein said recorder comprises:
a battery power source;
an analog to digital processing circuit which receives power from said power source;
a digital signal processing circuit which receives power from said power source;
an input signal detection circuit, wherein said input signal detection circuit monitors said communication link;
said method further comprising the steps of:
monitoring said communication link for incoming signals; and
shutting off power to said analog to digital processing circuit and to said digital signal processing circuit if no incoming signals are detected.

21. The method of claim 20, wherein said recorder further comprises a voice activated record circuit, further comprising the steps of:
monitoring the digitized word stream provided by said analog to digital processing circuit, and
enabling data storage if said digitized word stream exceeds a preset level.
